(19) United States
(12) Patent Application Publication
(10) Pub. No.: US 2026/0093893 A1
(43) Pub. Date: Apr. 2, 2026

(54) UNIFIED DEEP REINFORCEMENT LEARNING APPROACH FOR CONSTRUCTING RECTILINEAR AND OCTILINEAR STEINER MINIMUM TREES

(71) Applicant: FUZHOU UNIVERSITY, Fuzhou (CN)

(72) Inventors: Genggeng LIU, Fuzhou (CN); Zhenkun LIN, Fuzhou (CN); Wenzhong GUO, Fuzhou (CN)

(21) Appl. No.: 19/037,338

(22) Filed: Jan. 27, 2025

(30) Foreign Application Priority Data
Sep. 27, 2024 (CN) 202411358563.8

(51) Int. Cl. G06F 30/398; G06F 30/3953

(52) U.S. Cl. CPC G06F 30/398; G06F 30/3953

(57) ABSTRACT

Disclosed is a unified deep reinforcement learning approach for constructing rectilinear and octilinear Steiner minimum trees in the technical field of computer-aided design of integrated circuits, the method including designing an edge point sequence (EPS) based on structural characteristics of a Steiner minimum tree (SMT) to bridge a gap between deep learning model output and an SMT structure; designing a deep learning model for the EPS, and using a negative wirelength of the SMT as a reward to train the deep learning model through the deep reinforcement learning (DRL); providing a corresponding fast and accurate wirelength computation algorithm for a quality assessment of construction solutions to accelerate training of the deep learning model; and constructing diversified construction solutions of SMTs utilizing the stochastic nature of machine learning. The method of the present invention can solve rectilinear Steiner minimum tree (RSMT) and octilinear Steiner minimum tree (OSMT) problems and generate diversified routing topologies.

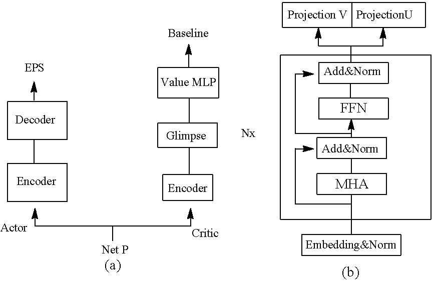

### TECHNICAL FIELD

The present invention relates to the technical field of computer-aided design of integrated circuits, and in particular, to a unified deep reinforcement learning approach for constructing rectilinear and octilinear Steiner minimum trees.

### BACKGROUND

Steiner minimum tree (SMT) construction, as a fundamental problem in very-large-scale-integration (VLSI) circuits, is widely used in the early stages of VLSI design, such as physical synthesis, floor planning, interconnect planning and layout, and can be used to estimate wire loads, congestion, and interconnect delays. SMT can be divided into Manhattan and non-Manhattan structures according to the routing direction of a routing tree. The construction of a rectilinear Steiner minimum tree (RSMT) of the Manhattan structure has been proven to be an NP-hard problem, while an octilinear Steiner minimum tree (OSMT) is a representative of the non-Manhattan structure. Compared with the RSMT routing mode, the OSMT routing mode adds 45° and 135° routing angles, and is widely used in heterogeneous integration. Following existing manufacturing processes, the OSMT can effectively reduce wirelength, interconnect delays, and via count, thereby speeding up the design process. However, the increase in routing angles also brings greater problem complexity. In addition, a given net may have an infinite number of SMTs. During a routing process, an SMT is often used to construct an initial routing topology of a net to optimize constraints such as total wirelength, routing congestion, and critical path delay. Interconnect optimizations such as buffer insertion also use an SMT to optimize timing and reduce dynamic power consumption. However, the complexity of the problem results in that traditional algorithms often only focus on constructing an optimal SMT for a given net, and the generated single routing topology is difficult to balance multiple constraints. An SMT that generates multiple routing topologies for each net can effectively optimize timing, reduce routing overflow, mitigate routing congestion, reduce total coupling capacitance, etc. Therefore, diversified construction solutions of SMTs are very important in a chip design process. With the development of machine learning (ML), it shows great potential to generate high-quality solutions to many NP-complete problems. Deep reinforcement learning (DRL) combines the perception capability of deep learning with the decision-making capability of reinforcement learning (RL), often showing more advantages than traditional methods.

### SUMMARY

The present invention is intended to solve rectilinear Steiner minimum tree (RSMT) and octilinear Steiner minimum tree (OSMT) problems and generate diversified routing topologies by providing a unified deep reinforcement learning approach for constructing rectilinear and octilinear Steiner minimum trees.

To achieve the foregoing objective, a technical solution of the present invention is a unified deep reinforcement learning approach for constructing rectilinear and octilinear Steiner minimum trees, including the following steps:
designing an edge point sequence (EPS) based on structural characteristics of a Steiner minimum tree (SMT);
designing a deep learning model for the EPS, and using a negative wirelength of the SMT as a reward to train the deep learning model through the deep reinforcement learning (DRL); and
constructing diversified construction solution of SMTs utilizing the stochastic nature of machine learning (ML).

In an embodiment of the present invention, during a training process of the deep learning model, a corresponding fast and accurate wirelength computation algorithm is provided for a quality assessment of the construction solutions to accelerate training of the deep learning model.

In an embodiment of the present invention, during a training process of the deep learning model, an input of the deep learning model is a pin sequence in a form of two-dimensional coordinates in a given net, and an output of the deep learning model is converted into a structure of the SMT through the EPS.

In an embodiment of the present invention, in the step of constructing diversified construction solutions of SMTs, a construction solution with the highest probability is selected through a greedy strategy, and random sampling is performed utilizing parallelizability of ML based on a probability generated by the deep learning model to generate the diversified construction solutions of SMTs.

In an embodiment of the present invention, the step of designing an edge point sequence (EPS) based on structural characteristics of a Steiner minimum tree (SMT) is aimed at building a capability of encoding both RSMT and OSMT structures as follows:
RSMT and OSMT construction problems are input as a set of nets P={p₁, . . . , pₙ}, where pins pᵢ are composed of coordinate pairs (xᵢ, yᵢ); connection points other than the pins introduced during routing are called pseudo-Steiner points represented by white squares; and given two of the pins a and b, four routing modes between the pins are as follows: routing mode 1: lead a vertical edge from the pin a to a pseudo-Steiner point s first, and then lead a horizontal edge from the point s to the pin b; routing mode 2: lead a horizontal edge from the pin a to the point s first, and then lead a vertical edge from the point s to the pin b; routing mode 3: lead a vertical or horizontal edge from the pin a to the point s first, and then lead a 45° or 135° edge from the point s to the pin b; and routing mode 4: lead a 45° or 135° edge from the pin a to the point s first, and then lead a vertical or horizontal edge from the point s to the pin b;
the RSMT structure is constructed so as to use only the routing mode 1 or 2 to build a rectilinear tree T(R) that connects all the pins in the net P and has the shortest wirelength, i.e. R is a superset (P⊆R) of P, where newly introduced points in R are Steiner points, the Steiner points can automatically cause overlapping edges to merge to achieve an effect of wirelength reduction, and the pseudo-Steiner points only exist during a routing optimization process and do not exist in the built RSMT; compared with the RSMT structure, the OSMT structure is constructed by adding the routing mode 3 or 4; and diversified RSMTs and OSMTs are constructed so as to construct as many high-quality routing topologies as possible for a given net; and
for a given net P={(x₁, y₁), . . . , (xₙ, yₙ)}, one EPS of P has n−1 pairs {[a₁, (b₁, e₁)], . . . , [aₙ₋₁, (bₙ₋₁, eₙ₋₁)]} where aₜ, bₜ∈{1, . . . , n}, eₜ∈{1, . . . , m}, and for t=1, . . . , n−1, i.e. in a t-th pair, an aₜ-th pin and a bₜ-th pin are connected by a routing mode eₜ; and in RSMT problem, m=2, while in OSMT problem, m=4.

In an embodiment of the present invention, the deep learning model uses an encoder-decoder architecture as follows:
the encoder is similar to a Transformer structure that maps two-dimensional coordinates of a pin to a 128-dimensional feature space through a linear layer, thereby mapping the pin from a low-dimensional coordinate representation to a high-dimensional vector, and uses batch normalization to make training more stable; in the RSMT and OSMT construction problems, one linear layer is used to learn feature vectors U of unvisited pins; in the RSMT problem, two linear mappings are used to learn features of visited pins in a routing mode 0 and the routing mode 1 and then spliced into V; and in the OSMT problem, four linear mappings are used to learn the features of the visited pins in the 4 routing modes and then spliced into; and
the decoder takes encoding results U=[u₁, . . . , uₙ]^{T} and V=[v₁, . . . , v_{m×n}]^{T} and as inputs and outputs the EPS of the SMT construction solution; the deep learning model first selects a uₐ_{₀} from U and marks a₀ as a visited pin, i.e. the pin can be selected subsequently when visited pins are chosen from V but it cannot be selected when unvisited pins are chosen; then, when a pair is chosen from the n−1 pairs, selection rules for the t-th pair are as follows: the deep learning model first selects an unvisited pin uₐ_{ₜ} each time, and then selects a v_{c}_{ₜ} from V, where bₜ=cₜ % n, ┌eₜ=cₜ/n┐, and aₜ is marked as a visited pin; pairs are added to the EPS in turn; and the deep learning model in the decoder uses an attention mechanism to select two pins in a pair and a routing mode between the pins.

In an embodiment of the present invention, the encoder uses a three-layer Transformer block, in which a multi-head attention mechanism uses 16 heads, a hidden layer of a feedforward neural network uses 512 dimensions, and layer normalization is replaced with the batch normalization.

In an embodiment of the present invention, during a training process of the deep learning model, a fast and accurate wirelength computation algorithm is provided as follows:
the algorithm takes as input the net P, a construction solution eps, and an SMT type indicator m; the construction solution eps is constructed for the RSMT structure when m=2 and for the OSMT structure when m=4; the horizontal edge Eₓ, the vertical edge E_{y}, and the 45° edge E_{z} or the 135° edge Eₖ are extracted based on eps, wherein E_{z} and Eₖ exist solely in a wirelength computation process of the OSMT structure; an extraction form is [left x-coordinate, right x-coordinate] for the horizontal edge, [lower y-coordinate, higher y-coordinate] for the vertical edge, and [starting x-coordinate, starting y-coordinate, ending x-coordinate, ending y-coordinate] for a hypotenuse; when a wirelength of the OSMT structure is computed, E_{z} and Eₖ are rotated by 45° counter-clockwise around an origin and transformed into the formats of the horizontal and vertical edges respectively to facilitate merging of the overlapping edges; and based on the edges extracted through pairwise traversal in eps, endpoint coordinates of each of the edges in the SMT are updated to merge overlapping line segments, and finally a total wirelength is computed.

In an embodiment of the present invention, the deep learning model includes two components: Actor and Critic; the Actor is configured to generate the EPS for the given net through a neural network, i.e. the Actor selects pairs based on probabilities generated by the model at each time step, and when a state for a subsequent time step consists of an SMT subtree determined by current EPS pairs, takes a negative wirelength of the resulting SMT as a reward; and the Critic is configured to predict the wirelength of the SMT constructed by the Actor and take it as a baseline to aid the Actor in learning, thereby enhancing its performance.

In an embodiment of the present invention, a policy-gradient-based Actor-Critic algorithm is used to train parameters of the Actor and the Critic so as to improve a probability of the neural network generating an excellent EPS; the Critic uses the same encoder structure as the Actor, but does not use ProjectionU and ProjectionV; the net P is taken as an input to generate an encoding result E′ through the encoder; the attention mechanism is used to calculate a proportional weight of each vectorized pin distribution to an overall encoding result; and subsequently, the baseline is computed through two fully-connected layers and an ReLU activation function.

Compared with the prior art, the present invention has the following beneficial effects: the method of the present invention includes designing an EPS based on structural characteristics of an SMT to bridge a gap between deep learning model output and an SMT structure; designing a deep learning model for the EPS, and using a negative wirelength of the SMT as a reward to train the deep learning model through the deep reinforcement learning (DRL); providing a corresponding fast and accurate wirelength computation algorithm for a quality assessment of construction solutions to accelerate training of the deep learning model; and constructing diversified construction solutions of SMTs utilizing the stochastic nature of machine learning. The method of the present invention can solve rectilinear Steiner minimum tree (RSMT) and octilinear Steiner minimum tree (OSMT) problems and generate diversified routing topologies.

### BRIEF DESCRIPTION OF THE DRAWINGS

FIG. 1 shows routing modes;

FIG. 2 shows an explanation of an edge point sequence; and

FIG. 3 shows a deep reinforcement learning framework.

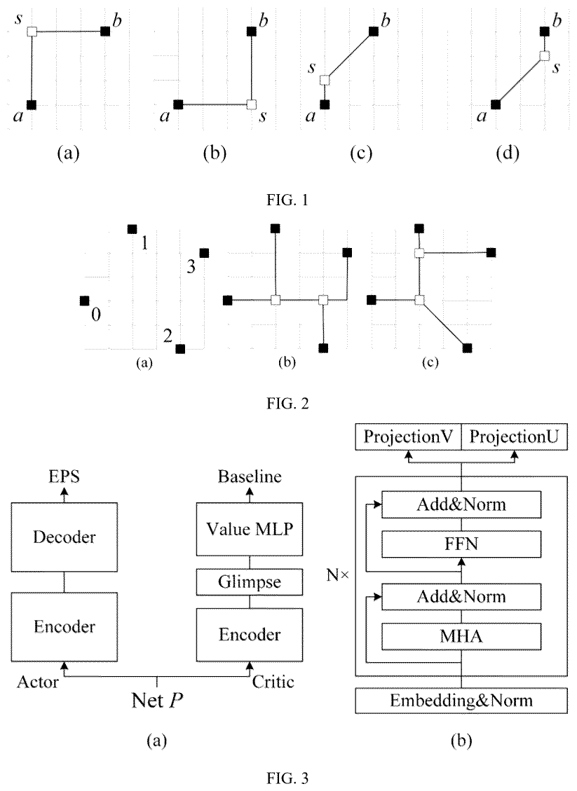

### DETAILED DESCRIPTION OF THE EMBODIMENTS

The technical solution of the present invention is described below in detail with reference to the accompanying drawings.

It should be noted that the following detailed description is exemplary and intended to further describe the present invention. Unless otherwise stated, all technical and scientific terms used herein have the same meanings as those generally understood by a person of ordinary skill in the art to which the present invention belongs.

It should be noted that the terms used herein are only for describing the embodiments rather than for limiting the exemplary embodiments of the present application. As used herein, unless otherwise stated clearly in the context, a singular form is intended to include a plural form thereof. In addition, it should be understood that the terms “comprise” and/or “include” as used herein indicate the presence of features, steps, operations, components, assemblies, and/or combinations thereof.

The present invention provides a unified deep reinforcement learning approach for constructing rectilinear and octilinear Steiner minimum trees, including the following steps:
designing an edge point sequence (EPS) based on structural characteristics of a Steiner minimum tree (SMT);
designing a deep learning model for the EPS, and using a negative wirelength of the SMT as a reward to train the deep learning model through the deep reinforcement learning (DRL); and
constructing diversified construction solutions of SMTs utilizing the stochastic nature of machine learning (ML).

During a training process of the deep learning model, a corresponding fast and accurate wirelength computation algorithm is provided for a quality assessment of the construction solutions to accelerate training of the deep learning model.

The specific implementation process of the present invention is as follows.

An embodiment of the present invention provides a unified deep reinforcement learning approach for constructing rectilinear and octilinear Steiner minimum trees as follows:

### 1. Routing Mode

RSMT and OSMT construction problems are input as a set of nets P={p₁, . . . , pₙ}, where pins pᵢ are composed of coordinate pairs (xᵢ, yᵢ); connection points other than the pins introduced during routing are called pseudo-Steiner points represented by white squares; and given two of the pins a and b, four routing modes between the pins are as follows: routing mode 1: lead a vertical edge from the pin a to a pseudo-Steiner point s first, and then lead a horizontal edge from the point s to the pin b; routing mode 2: lead a horizontal edge from the pin a to the point s first, and then lead a vertical edge from the point s to the pin b; routing mode 3: lead a vertical or horizontal edge from the pin @ to the point s first, and then lead a 45° or 135° edge from the point s to the pin b; and routing mode 4: lead a 45° or 135° edge from the pin a to the point s first, and then lead a vertical or horizontal edge from the point s to the pin b.

The RSMT structure is constructed so as to use only the routing mode 1 or 2 to build a rectilinear tree T(R) that connects all the pins in the net P and has the shortest wirelength, i.e. R is a superset (P⊆R) of P, where newly introduced points in R are Steiner points, the Steiner points can automatically cause overlapping edges to merge to achieve an effect of wirelength reduction, and the pseudo-Steiner points only exist during a routing optimization process and do not exist in the built RSMT; compared with the RSMT structure, the OSMT structure is constructed by adding the routing mode 3 or 4; and diversified RSMTs and OSMTs are constructed so as to construct as many high-quality routing topologies as possible for a given net.

### 2. Edge Point Sequence (EPS)

For a given net P={(x₁, y₁), . . . , (xₙ, yₙ)}, one EPS of P has n−1 pairs {[a₁, (b₁, e₁)], . . . , [aₙ₋₁, (bₙ₋₁, eₙ₋₁)]}, where aₜ, bₜ∈{1, . . . , n}, eₜ∈{1, . . . , m}, and for t=1, . . . , n−1, i.e. in a t-th pair, an aₜ-th pin and a bₜ-th pin are connected by a routing mode eₜ; and in RSMT problem, m=2, while in OSMT problem, m=4. For example, given a net P={(0, 2), (2,5), (4,0), (5,4)}, the position of each pin is shown in FIG. 2(a). A feasible RSMT solution of P is eps₁={[1, (3, 2)], [4, (1,1)], [2, (1,1)]} which is the optimal RSMT as shown in FIG. 2(b). A feasible OSMT solution is eps₂={[1, (2,2)], [4, (2, 2)], [3, (1, 4)]}, which is the optimal OSMT as shown in FIG. 2(c).

### 3. Neural Network Model

The neural network model uses an encoder-decoder architecture. The encoder is similar to a Transformer structure that maps two-dimensional coordinates of a pin to a 128-dimensional feature space through a linear layer, thereby mapping the pin from a low-dimensional coordinate representation to a high-dimensional vector, and uses batch normalization to make training more stable. In specific implementations, the encoder uses a three-layer Transformer block, in which a multi-head attention mechanism uses 16 heads, a hidden layer of a feedforward neural network uses 512 dimensions, and layer normalization is replaced with the batch normalization. In the RSMT and OSMT construction problems, one linear layer is used to learn feature vectors U of unvisited pins; in the RSMT problem, two linear mappings are used to learn features of visited pins in the routing mode 1 and the routing mode 2 and then spliced into V; and in the OSMT problem, four linear mappings are used to learn the features of the visited pins in the 4 routing modes and then spliced into V. The overall structure of the encoder is shown in FIG. 3(a).

The decoder takes encoding results U=[u₁, . . . , uₙ]^{T} and V=[v₁, . . . , v_{m×n}]^{T} as inputs and outputs the EPS of the SMT construction solution. The neural network first selects a uₐ_{₀} do from U and marks a₀ as a visited pin (i.e. the pin can be selected subsequently when visited pins are chosen from V but it cannot be selected when unvisited pins are chosen). Then, when a pair is chosen from the n−1 pairs, selection rules for the t-th pair are as follows: the neural network first selects an unvisited pin uₐ_{ₜ} each time, and then selects a v_{c}_{ₜ} from V (where bₜ=cₜ % n, ┌eₜ=cₜ/n┐), and aₜ is marked as a visited pin. Pairs are added to the EPS in turn. The neural network in the decoder uses an attention mechanism to select two pins in a pair and a routing mode between the pins.

### 4. Fast and Accurate Wirelength Computation Algorithm

The algorithm takes as input the net P, a construction solution eps, and an SMT type indicator m; the construction solution eps is constructed for the RSMT structure when m=2 and for the OSMT structure when m=4; the horizontal edge Eₓ, the vertical edge E_{y}, and the 45° edge E_{z} or the 135° edge Eₖ are extracted based on eps, wherein E_{z} and Eₖ exist solely in a wirelength computation process of the OSMT structure; an extraction form is [left x-coordinate, right x-coordinate] for the horizontal edge, [lower y-coordinate, higher y-coordinate] for the vertical edge, and [starting x-coordinate, starting y-coordinate, ending x-coordinate, ending y-coordinate] for a hypotenuse; when a wirelength of the OSMT structure is computed, E_{z} and Eₖ are rotated by 45° counter-clockwise around an origin and transformed into the formats of the horizontal and vertical edges respectively to facilitate merging of the overlapping edges; and based on the edges extracted through pairwise traversal in eps endpoint coordinates of each of the edges in the SMT are updated to merge overlapping line segments, and finally a total wirelength is computed.

### 5. Training Method

FIG. 3(b) shows a DRL framework for constructing an SMT. The model mainly includes two components: Actor and Critic. The Actor is configured to generate the EPS for the given net through a neural network, i.e. the Actor selects pairs based on probabilities generated by the model at each time step, and when a state for a subsequent time step consists of an SMT subtree determined by current EPS pairs, takes a negative wirelength of the resulting SMT as a reward. The Critic is configured to predict the wirelength of the SMT constructed by the Actor and take it as a baseline to aid the Actor in learning, thereby enhancing its performance. A policy-gradient-based Actor-Critic algorithm is used to train parameters of the Actor and the Critic so as to improve a probability of the neural network generating an excellent EPS. The Critic uses the same encoder structure as the Actor, but does not use ProjectionU and ProjectionV. The net P is taken as an input to generate an encoding result E′ through the encoder. The attention mechanism is used to calculate a proportional weight of each vectorized pin distribution to an overall encoding result. Subsequently, the baseline is computed through two fully-connected layers and an ReLU activation function.

The present invention further provides a unified system for constructing rectilinear and octilinear Steiner minimum trees based on deep reinforcement learning, including a memory, a processor, and a computer program instruction stored on the memory and executable by the processor, where the processor implements the steps of the method described above when executing the computer program instruction.

The present invention further provides a computer-readable storage medium on which a computer program instruction executable by a processor is stored. When the processor executes the computer program instruction, the steps of the method described above can be implemented.

Those skilled in the art should understand that the embodiments of the present application may be provided as a method, a system, or a computer program product. Therefore, the present application may be in the form of a hardware only embodiment, a software only embodiment, or an embodiment with a combination of software and hardware. Moreover, the present application may be in the form of a computer program product that is implemented on one or more computer-usable storage media (including but not limited to a disk memory, a CD-ROM, an optical memory, and the like) that include computer-usable program code.

The present application is described with reference to flow charts and/or block diagrams of methods, devices (systems), and computer program products according to embodiments of the present application. It should be understood that computer program instructions may be used to implement each process and/or each block in the flow charts and/or the block diagrams and a combination of a process and/or a block in the flow charts and/or the block diagrams. These computer program instructions may be provided for a general-purpose computer, a dedicated computer, an embedded processor, or a processor of another programmable data processing device to generate a machine, so that the instructions executed by a computer or a processor of another programmable data processing device generate an apparatus for implementing a specific function in one or more processes in the flowcharts and/or in one or more blocks in the block diagrams.

These computer program instructions may be stored in a computer readable memory that can instruct the computer or another programmable data processing device to work in a specific manner, so that the instructions stored in the computer readable memory generate an artifact that includes an instruction apparatus. The instruction apparatus implements a specific function in one or more processes in the flowcharts and/or in one or more blocks in the block diagrams.

These computer program instructions may also be loaded onto a computer or another programmable data processing device, so that a series of operation steps are performed on the computer or another programmable device to generate computer-implemented processing. Therefore, the instructions executed on the computer or another programmable device are used to provide steps for implementing a specific function in one or more processes in the flowcharts and/or in one or more blocks in the block diagrams.

The above-described embodiments are only exemplary embodiments of the present invention and constitute no restriction in any form on the present invention. Those skilled in the art may make some changes or modifications to equivalent embodiments with equivalent changes by reference to the technical content disclosed above. However, any simple revisions, equivalent changes, and modifications made to the above embodiments in accordance with the technical essence of the present invention without departing from the content of the technical solutions of the present invention shall still fall within the protection scope of the technical solutions of the present invention.

What is claimed is:

1. A unified deep reinforcement learning approach for constructing rectilinear and octilinear Steiner minimum trees, comprising the following steps:
designing an edge point sequence (EPS) based on structural characteristics of a Steiner minimum tree (SMT);
designing a deep learning model for the EPS, and using a negative wirelength of the SMT as a reward to train the deep learning model through the deep reinforcement learning (DRL); and
constructing diversified construction solutions of SMTs utilizing the stochastic nature of machine learning (ML).

2. The unified deep reinforcement learning approach for constructing rectilinear and octilinear Steiner minimum trees of claim 1, wherein during a training process of the deep learning model, a corresponding fast and accurate wirelength computation algorithm is provided for a quality assessment of the construction solutions to accelerate training of the deep learning model.

3. The unified deep reinforcement learning approach for constructing rectilinear and octilinear Steiner minimum trees of claim 1, wherein during a training process of the deep learning model, an input of the deep learning model is a pin sequence in a form of two-dimensional coordinates in a given net, and an output of the deep learning model is converted into a structure of the SMT through the EPS.

4. The unified deep reinforcement learning approach for constructing rectilinear and octilinear Steiner minimum trees of claim 1, wherein in the step of constructing diversified construction solutions of SMTs, a construction solution with the highest probability is selected through a greedy strategy, and random sampling is performed utilizing parallelizability of ML based on a probability generated by the deep learning model to generate the diversified construction solution of SMTs.

5. The unified deep reinforcement learning approach for constructing rectilinear and octilinear Steiner minimum trees claim 1, wherein the step of designing an edge point sequence (EPS) based on structural characteristics of a Steiner minimum tree (SMT) is aimed at building a capability of encoding both rectilinear Steiner minimum tree (RSMT) and octilinear Steiner minimum tree (OSMT) structures as follows:
RSMT and OSMT construction problems are input as a set of nets P={p₁, . . . , pₙ} wherein pins pᵢ are composed of coordinate pairs (xᵢ, yᵢ); connection points other than the pins introduced during routing are called pseudo-Steiner points represented by white squares; and given two of the pins a and b, four routing modes between the pins are as follows: routing mode 1: lead a vertical edge from the pin a to a pseudo-Steiner point s first, and then lead a horizontal edge from the point s to the pin b; routing mode 2: lead a horizontal edge from the pin a to the point s first, and then lead a vertical edge from the point s to the pin b; routing mode 3: lead a vertical or horizontal edge from the pin a to the point s first, and then lead a 45° or 135° edge from the point s to the pin b; and routing mode 4: lead a 45° or 135° edge from the pin a to the point s first, and then lead a vertical or horizontal edge from the point s to the pin b;
the RSMT structure is constructed so as to use only the routing mode 1 or 2 to build a rectilinear tree T(R) that connects all the pins in the net P and has the shortest wirelength, i.e. R is a superset (P⊆R) of P, wherein newly introduced points in R are Steiner points, the Steiner points can automatically cause overlapping edges to merge to achieve an effect of wirelength reduction, and the pseudo-Steiner points only exist during a routing optimization process and do not exist in the built RSMT; compared with the RSMT structure, the OSMT structure is constructed by adding the routing mode 3 or 4; and diversified RSMTs and OSMTs are constructed so as to construct as many high-quality routing topologies as possible for a given net; and
for a given net P={(x₁, y₁), . . . , (xₙ, yₙ)}, one EPS of P has n−1 pairs {[a₁, (b₁, e₁)], . . . , [aₙ₋₁, (bₙ₋₁, eₙ₋₁)]}, wherein aₜ, bₜ∈{1, . . . , n}, eₜ∈{1, . . . , m}, and for t=1, . . . , n−1, i.e. in a t-th pair, an aₜ-th pin and a bₜ-th pin are connected by a routing mode eₜ; and in RSMT problem, m=2, while in OSMT problem, m=4.

6. The unified deep reinforcement learning approach for constructing rectilinear and octilinear Steiner minimum trees claim 5, wherein the deep learning model uses an encoder-decoder architecture as follows:
the encoder is similar to a Transformer structure that maps two-dimensional coordinates of a pin to a 128-dimensional feature space through a linear layer, thereby mapping the pin from a low-dimensional coordinate representation to a high-dimensional vector, and uses batch normalization to make training more stable; in the RSMT and OSMT construction problems, one linear layer is used to learn feature vectors U of visited pins; in the RSMT problem, two linear mappings are used to learn features of visited pins in a routing mode 0 and the routing mode 1 and then spliced into V; and in the OSMT problem, four linear mappings are used to learn the features of the visited pins in the 4 routing modes and then spliced into V; and
the decoder takes encoding results U=[u₁, . . . , uₙ]T and V=[v₁, . . . , v_{m×n}]^{T} as inputs and outputs the EPS of the SMT construction solution; the deep learning model first selects a uₐ_{₀} from U and marks a₀ as a visited pin, i.e. the pin can be selected subsequently when visited pins are chosen from V but it cannot be selected when unvisited pins are chosen; then, when a pair is chosen from the n−1 pairs, selection rules for the t-th pair are as follows: the deep learning model first selects an unvisited pin uₐ_{ₜ} each time, and then selects a v_{c}_{ₜ} from V, wherein bₜ=cₜ % n, ┌cₜ/n┐, and aₜ is marked as a visited pin; pairs are added to the EPS in turn; and the deep learning model in the decoder uses an attention mechanism to select two pins in a pair and a routing mode between the pins.

7. The unified deep reinforcement learning approach for constructing rectilinear and octilinear Steiner minimum trees claim 6, wherein the encoder uses a three-layer Transformer block, in which a multi-head attention mechanism uses 16 heads, a hidden layer of a feedforward neural network uses 512 dimensions, and layer normalization is replaced with the batch normalization.

8. The unified deep reinforcement learning approach for constructing rectilinear and octilinear Steiner minimum trees claim 5, wherein during a training process of the deep learning model, a fast and accurate wirelength computation algorithm is provided as follows:
the algorithm takes as input the net P, a construction solution eps, and an SMT type indicator m; the construction solution eps is constructed for the RSMT structure when m=2 and for the OSMT structure when m=4; the horizontal edge Eₓ, the vertical edge E_{y}, and the 45° edge E_{z} or the 135° edge Eₖ are extracted based on eps, wherein E_{z} and Eₖ exist solely in a wirelength computation process of the OSMT structure; an extraction form is [left x-coordinate, right x-coordinate] for the horizontal edge, [lower y-coordinate, higher y-coordinate] for the vertical edge, and [starting x-coordinate, starting y-coordinate, ending x-coordinate, ending y-coordinate] for a hypotenuse; when a wirelength of the OSMT structure is computed, E_{z} and Eₖ are rotated by 45° counter-clockwise around an origin and transformed into the formats of the horizontal and vertical edges respectively to facilitate merging of the overlapping edges; and based on the edges extracted through pairwise traversal in eps, endpoint coordinates of each of the edges in the SMT are updated to merge overlapping line segments, and finally a total wirelength is computed.

9. The unified deep reinforcement learning approach for constructing rectilinear and octilinear Steiner minimum trees claim 6, wherein the deep learning model comprises two components: Actor and Critic; the Actor is configured to generate the EPS for the given net through a neural network, i.e. the Actor selects pairs based on probabilities generated by the model at each time step, and when a state for a subsequent time step consists of an SMT subtree determined by current EPS pairs, takes a negative wirelength of the resulting SMT as a reward; and the Critic is configured to predict the wirelength of the SMT constructed by the Actor and take it as a baseline to aid the Actor in learning, thereby enhancing its performance.

10. The unified deep reinforcement learning approach for constructing rectilinear and octilinear Steiner minimum trees claim 9, wherein a policy-gradient-based Actor-Critic algorithm is used to train parameters of the Actor and the Critic so as to improve a probability of the neural network generating an excellent EPS; the Critic uses the same encoder structure as the Actor, but does not use ProjectionU and ProjectionV; the net P is taken as an input to generate an encoding result E′ through the encoder; the attention mechanism is used to calculate a proportional weight of each vectorized pin distribution to an overall encoding result; and subsequently, the baseline is computed through two fully-connected layers and an ReLU activation function.
